(19) United States
(12) Patent Application Publication
(10) Pub. No.: US 2012/0221903 A1
(43) Pub. Date: Aug. 30, 2012

(54) TESTING METHOD, NON-TRANSITORY, COMPUTER READABLE STORAGE MEDIUM AND TESTING APPARATUS

(75) Inventor: Tadashi OHNUMA, Kawasaki (JP)

(73) Assignee: Fujitsu Limited, Kawasaki (JP)

(21) Appl. No.: 13/362,325

(22) Filed: Jan. 31, 2012

(30) Foreign Application Priority Data
Feb. 24, 2011 (JP) 2011-038292

(51) Int. Cl. G11C 29/10; G06F 11/263

(52) U.S. Cl. 714/720; 714/E11.177

(57) ABSTRACT

A method for testing data, has writing, in a first area of the test-target area, a test pattern, transferring, to a second area of the test-target area, the test pattern that has been written in the first area, transferring, to the first area, the test pattern that has been transferred to the second area, using as a transfer start address an address that is shifted by a predetermined amount, and inspecting whether or not the data is correctly written in and read from the test-target area by comparing the base patterns disposed next to each other in the base-pattern pair included in the test pattern that has been transferred from one of the first area and the second area to the other of the first area and the second area and by determining whether or not the base patterns disposed next to each other are identical to one another.

### CROSS-REFERENCE TO RELATED APPLICATION

This application is based upon and claims the benefit of priority of the prior Japanese Patent Application No. 2011-038292, filed on Feb. 24, 2011, the entire contents of which are incorporated herein by reference.

### FIELD

The embodiment discussed herein relate to a testing method, a non-transitory, computer readable storage medium and a testing apparatus for testing storage devices for use in information processing apparatuses.

### BACKGROUND

In computer systems, such as servers, a memory test may be performed on memories (storage devices), such as random access memories (RAMs) (see, for example, Japanese Laid-open Patent Publication Nos. H05-334899 and 2002-343097). One type of such a memory test is intended for detection of memory failures caused by factors, such as voltage fluctuations and insufficient noise margins. It is known that, in the memory test of this type, a load is placed on memories by performing an accelerated test to do the test in a short time.

In the accelerated test, for example, an amount of data to be transferred to a memory per unit time is increased or data is evenly transferred to different representative addresses in a memory instead of testing the entire memory. Block transfer is known as one of effective methods for realizing the aforementioned accelerated test. The following techniques are used in block transfer.

For example, in block transfer, a technique for comparing data stored in a transfer source with data stored in a transfer destination is used in order to detect whether or not data is corrupted because of data transfer. In block transfer, transfer is repeatedly performed a plurality of times in order to place a load on memories. To avoid a situation where the same data is repeatedly written in the same memory area, a technique for shifting addresses of the transfer source and the transfer destination is used.

For example, the addresses of the transfer source and the transfer destination are shifted by an amount equal to the size of a cache memory of a central processing unit (CPU). In the case where the addresses of the transfer source and the transfer destination are shifted by the amount equal to the size of the cache memory of the CPU, data stored in the cache memory is continuously transferred in a burst. Meanwhile, burst transfer is a function for dividing data stored in the cache memory into as many data portions as a value obtained by dividing the size of the cache memory of the CPU by the bus width of the memory, and continuously transferring the data portions one by one. For example, when the size of the cache memory of the CPU is 32 bytes and the bus width of the memory is 8 bytes, four 8-byte data portions of the 32-byte data stored in the cache memory are continuously transferred one by one.

During burst transfer, data transfer is not interrupted and, thus, the continuity of the data stored in the cache memory is guaranteed.

With the recent demands for computer systems having a larger scale and a larger memory capacity, capacities of memories are steadily increasing. The increase in the memory capacity leads to an increase in a time spent on the memory test performed using existing memory test techniques intended for detection of memory failures. However, the memory test intended for detection of memory failures caused by factors, such as voltage fluctuations and insufficient noise margins, is desirably performed in a short time.

The memory test using the aforementioned block transfer involves the following concerns (i) to (iii) regarding execution of the test in a short time and improvement of the accuracy of the test. (i) Although whether or not data stored in a transfer source matches data stored in a transfer destination is determined with the technique for comparing the data stored in the transfer source with the data stored in the transfer destination, whether or not the data itself is corrupted is not detectable with the technique. For example, in the case where the data stored in the transfer source has already been corrupted before data is transferred, the corrupted data is written in the transfer destination and, therefore, a failure is undetectable from comparison of the pieces of data.

### SUMMARY

According to an aspect of an embodiment, a testing method for testing whether or not data is correctly written in and read from a test-target area of a storage unit included in an information processing apparatus, by using a processor included in the information processing apparatus, the testing method has writing, in a first area of the test-target area, a test pattern including a base-pattern pair constituted by identical base patterns disposed next to each other, transferring, to a second area of the test-target area, the test pattern that has been written in the first area, transferring, to the first area, the test pattern that has been transferred to the second area, using as a transfer start address an address that is shifted by a predetermined amount from a write start address from which the test pattern has been written in the first area, and inspecting whether or not the data is correctly written in and read from the test-target area by comparing the base patterns disposed next to each other in the base-pattern pair included in the test pattern that has been transferred from one of the first area and the second area to the other of the first area and the second area and by determining whether or not the base patterns disposed next to each other are identical to one another.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a diagram illustrating an example of a hardware configuration of an information processing apparatus according to an embodiment.

FIG. 2 is a block diagram illustrating an example of a functional configuration of the information processing apparatus according to the embodiment.

FIG. 3 is a diagram illustrating an example of a shift pattern for use in a memory test according to the embodiment.

FIG. 4 is a diagram illustrating an example of a noise pattern for use in a memory test according to the embodiment.

FIG. 5 is a diagram describing a procedure of burst transfer performed by a test pattern transferring unit according to the embodiment.

FIGS. 6A to 6F are diagram illustrating arrangements of data in a test-target area of a memory when the test pattern transferring unit according to the embodiment performs burst transfer.

FIG. 7 is a diagram illustrating data patterns generated when the test pattern transferring unit according to the embodiment performs burst transfer.

FIGS. 8A and 8B are diagrams illustrating burst-transfer unit data transferred in burst transfer performed by the test pattern transferring unit according to the embodiment.

FIG. 9 is a diagram illustrating comparison of adjacent data patterns in the test-target area of the memory performed by a determining unit according to the embodiment.

FIG. 10 is a flowchart for describing a testing method for testing a memory according to the embodiment.

FIG. 11 is a diagram illustrating results of data transfer and comparison when data stored in a transfer source of a test-target area of a memory is corrupted after the data stored in the transfer source is compared with data stored in a transfer destination.

FIG. 12 is a diagram illustrating arrangements of data in the storage area of the memory before and after burst transfer is performed.

FIG. 13 is a diagram illustrating data patterns generated in burst transfer.

FIG. 14 is a diagram illustrating burst-transfer unit data transferred in burst transfer.

### DESCRIPTION OF EMBODIMENT

An Embodiment will be described below with reference to the accompanying drawings.

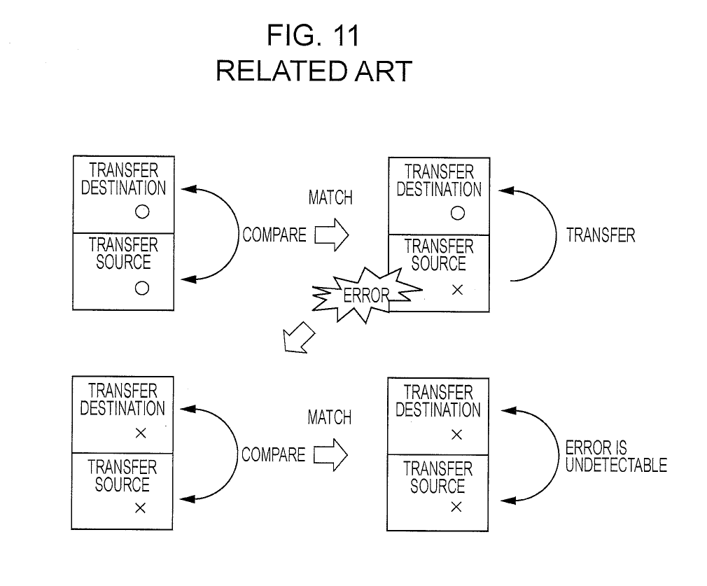

FIG. 11 is a diagram illustrating results of data transfer and comparison when data stored in a transfer source in a storage area of a memory is corrupted after the data stored in the transfer source is compared with data stored in a transfer destination. For example, as illustrated in FIG. 11, it is detected that the data stored in the transfer source matches the data stored in the transfer destination as a result of comparison (an upper left figure in FIG. 11). An error then occurs in the data stored in the transfer source, and the corrupted data is transferred to the transfer destination (an upper right figure in FIG. 11). In this case, since both the transfer source and the transfer destination store the corrupted data, it is detected that the data stored in the transfer source matches the data stored in the transfer destination as a result of comparison (a lower left figure in FIG. 11).

Accordingly, when the data stored in the transfer source is corrupted after the comparison of the data stored in the transfer source with the data stored in the transfer destination, the error is not detected from the comparison of the data stored in the transfer source with the data stored in the transfer destination (a lower right figure in FIG. 11). (ii) To guarantee that data stored in a test-target area (the transfer source or the transfer destination) is normal after repetition of transfer a plurality of times, i.e., that transfer has been successfully performed, block transfer is desirably simulated in advance to prepare data of expected values. Accordingly, a large amount of data, such as data of expected values, is loaded from an external storage device or the like, and then comparison is performed. For this reason, lots of time is spent on the comparison.

In addition, since the data stored in the transfer source is compared with the data stored in the transfer destination every time transfer is performed, lots of time is spent on the comparison. (iii) When addresses of the transfer source and the transfer destination are shifted by an amount equal to the size of a cache memory, a string of data stored in the cache memory is typically transferred continuously in a burst. However, transfer of one string of data stored in the cache memory at one time point and the following string of data stored in the cache memory at the next time point is interrupted at boundaries of burst transfer. Regarding a test using a noise pattern, an effective test may be performed on condition that the preceding and following strings of data to be transferred are consecutive. However, transfer of one string of data stored in the cache memory at one time point and the following string of data stored in the cache memory at the next time point is interrupted at boundaries of the burst transfer and, therefore, the accuracy of the test decreases.

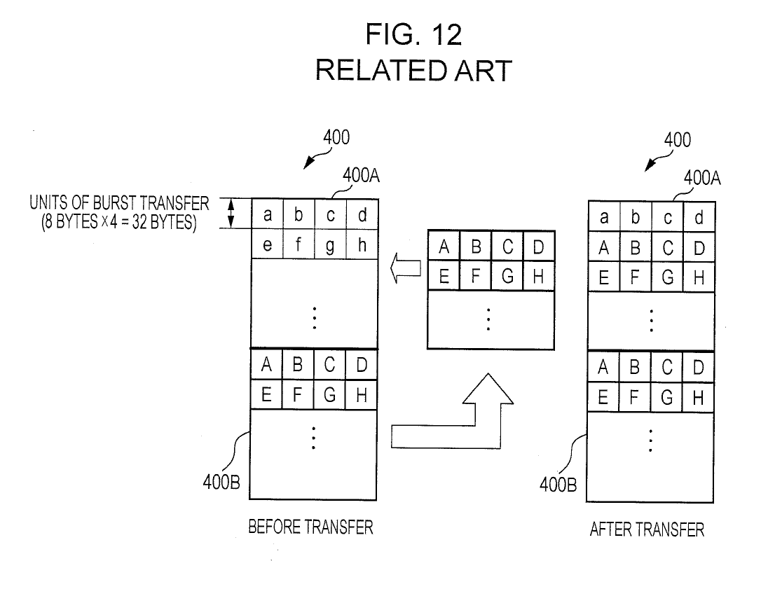

Meanwhile, the noise pattern indicates data that is constituted by a plurality of data elements and is used in inspection of noise margins. For example, the noise pattern may be data obtained by alternately disposing “5555 . . . (H)” and “AAAA . . . (H)” which are likely to cause crosstalk noise. FIG. 12 is a diagram illustrating arrangements of data in a storage area of a memory before and after burst transfer is performed in which addresses of a transfer destination and a transfer source are shifted by an amount equal to units of burst transfer. It is assumed here that the bus width of a memory and the units of burst transfer are 8 bytes and 32 bytes, respectively.

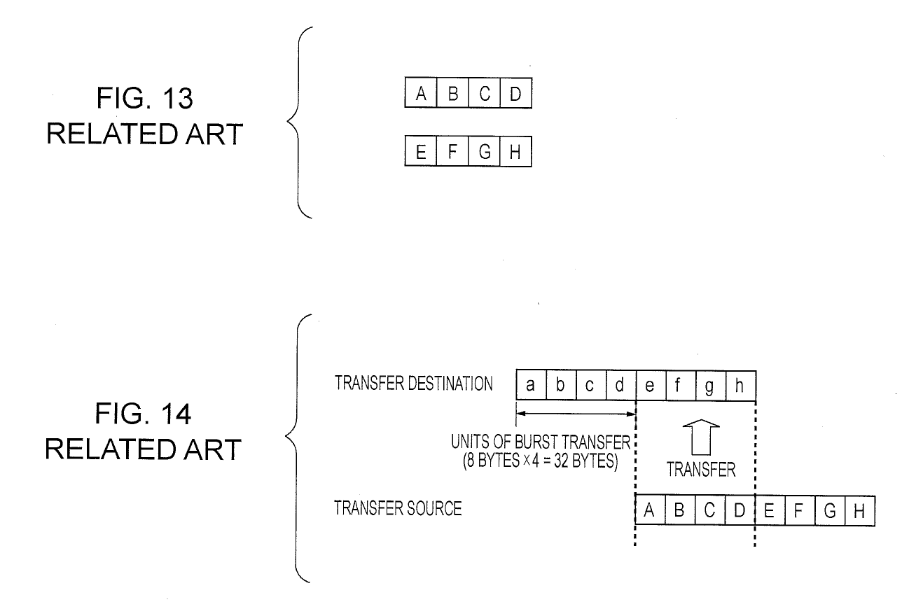

FIG. 13 is a diagram illustrating data patterns generated in burst transfer illustrated in FIG. 12. FIG. 14 is a diagram illustrating burst-transfer unit data transferred in burst transfer illustrated in FIG. 12. In FIGS. 12 to 14, a block denoted by each of “a” to “h” and “A” to “H” represents an 8-byte unit pattern. As described above, since the size of the cache memory is used as the units of burst transfer, the CPU transfers four blocks, which are obtained by dividing the size of the cache memory, i.e., 32 bytes, by the bus width of the memory (the size of the unit pattern), i.e., 8 bytes, during one burst transfer process.

In the example illustrated in FIG. 12, data stored in a transfer source area 400B is transferred to a transfer destination area 400A in a burst in a test-target area 400 of a storage area of a memory. At this time, the start address in the area 400A to which the data is to be transferred is an address that is shifted from the head address of the area 400A by an amount equal to the units of burst transfer, i.e., 32 bytes. Accordingly, in FIG. 12, the data stored in the area 400B is transferred in a burst in units of 32 bytes, using as a transfer start address an address of the block denoted by “e” in the area 400A in a state before transfer.

When the address of the transfer destination is shifted by the amount equal to the units of burst transfer in burst transfer, two data patterns, i.e. “ABCD” and “EFGH” illustrated in FIG. 13, appear as consecutive strings of data. For example, as illustrated in FIG. 14, boundaries of burst transfer exist between “A” and “H” and between “D” and “E” as a result of execution of burst transfer. Accordingly, even when burst transfer is repeatedly performed a plurality of times, data transfer is interrupted at these boundaries of burst transfer.

As described above, data transfer of one string of data stored in the cache memory at one time point and the following string of data stored in the cache memory at the next time point is interrupted at boundaries of burst transfer when the addresses of the transfer source and the transfer destination are shifted by an amount equal to the size of the cache memory and, therefore, the accuracy of the test decreases.

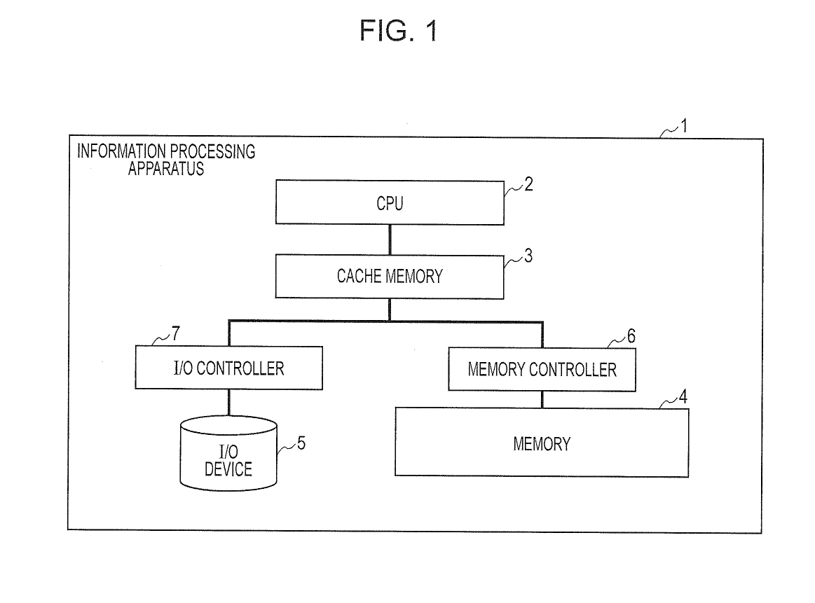

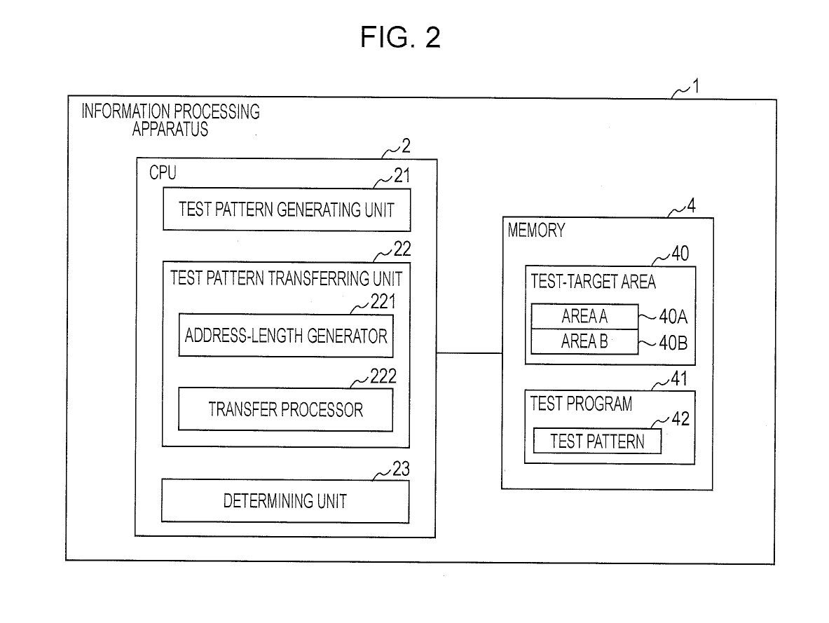

FIG. 1 is a diagram illustrating an example of a hardware configuration of an information processing apparatus 1 according to an embodiment. FIG. 2 is a diagram illustrating an example of a functional configuration of the information processing apparatus 1 according to the embodiment. The information processing apparatus 1 illustrated in FIG. 1 performs a test intended for detection of memory failures on a test-target area 40 of a memory 4 (storage section) by using block transfer.

The information processing apparatus 1 includes a central processing unit (CPU) 2 (processing section), the memory 4, a cache memory 3 that stores data to be transferred between the CPU 2 and the memory 4 and reference information of the data, a memory controller 6 that controls access from the CPU 2 to the memory 4. The information processing apparatus 1 also includes an input/output (I/O) device 5, such as a hard disk drive (HDD), and an I/O controller 7 that controls input and output of data performed between the I/O device 5 and the CPU 2.

In this embodiment, the illustrative description will be given for a case where the cache memory 3 has a size of 32 bytes. As illustrated in FIG. 2, the memory 4 includes the test-target area 40 subjected to a memory test performed by the CPU 2. Hereinafter, a first half part of the test-target area 40 used in the memory test is referred to as an area 40A (first area), whereas a last half part of the test-target area 40 is referred to as an area 40B (second area).

The areas 40A and 40B preferably have the same capacity. In this embodiment, the description will be given based on an assumption that the areas 40A and 40B have the same capacity. Hereinafter, the area 40A and the area 40B are simply referred to as an area A and an area B, respectively. The memory 4 is connected to the CPU 2 via a bus having a width of 8 bytes. As the memory 4, a random access memory (RAM), for example, may be used.

In this embodiment, the CPU 2 loads a test program 41 stored in the I/O device 5 into the memory 4 and executes the test program 41, whereby the information processing apparatus 1 performs a test on the test-target area 40 of the memory 4. The information processing apparatus 1 examines whether or not data is correctly written in and read out from the test-target area 40 of the memory 4. In the memory test, the CPU 2 writes data in the test-target area 40 of the memory 4 by burst transfer. In this embodiment, the CPU 2 divides data having a size of 32 bytes, which is equal to the size of cache memory 3, into four data portions each having a size of 8 bytes, which is equal to the bus width of the memory 4, and continuously transfers the four 8-byte data portions one by one, thereby performing burst transfer.

In addition, as illustrated in FIG. 2, the CPU 2 has functions of a test pattern generating unit 21 (generating unit), a test pattern transferring unit 22 (transferring unit), and a determining unit 23. The test pattern generating unit 21 generates a test pattern 42 that includes a base-pattern pair in which adjacent base patterns are identical, i.e., a base-pattern pair constituted by identical base patterns disposed next to each other. The test pattern generating unit 21 then writes the test pattern 42 in the area A of the test-target area 40. At this time, the test pattern generating unit 21 writes the test pattern 42, using the head address of the area A as a write start address.

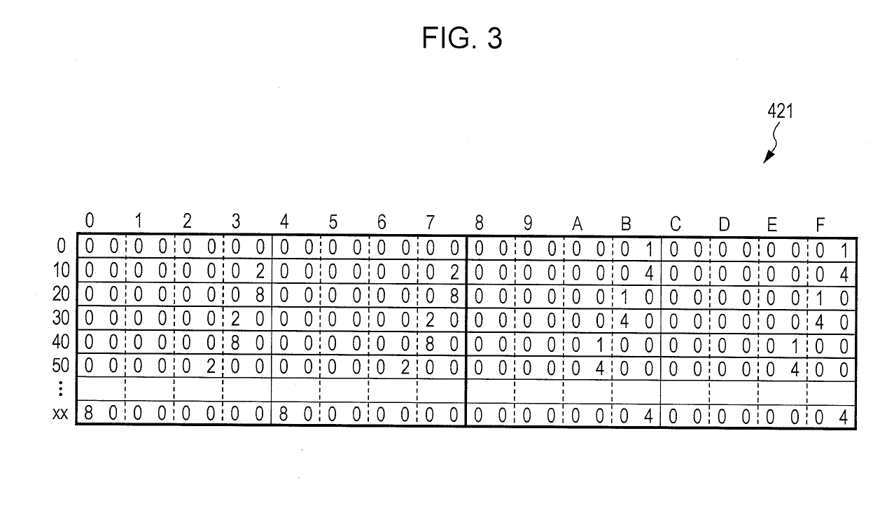

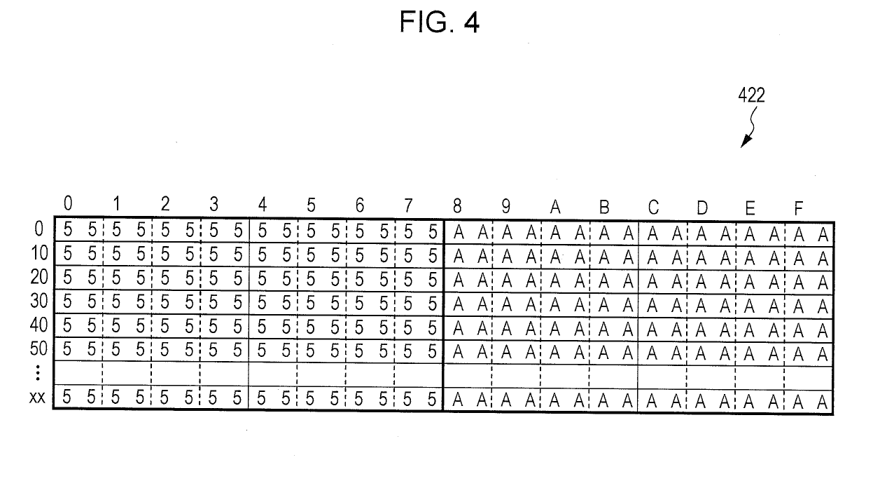

The test pattern 42 may include a plurality of the base-pattern pairs. The illustrative description will be given below for a case where the test pattern 42 includes a plurality of base-pattern pairs each constituted by identical base patterns disposed next to each other. Examples of the test pattern 42 include a shift pattern 421 illustrated in FIG. 3 and a noise pattern 422 illustrated in FIG. 4.

FIG. 3 is a diagram illustrating an example of the shift pattern 421 for use in the memory test according to this embodiment. FIG. 4 is a diagram illustrating an example of the noise pattern 422 for use in the memory test according to this embodiment. Numerical values included in FIGS. 3 and 4 are represented in hexadecimal notation. As illustrated in FIG. 3, the shift pattern 421 includes a plurality of base-pattern pairs, such as those held in bytes “0 to 7”, bytes “8 to F”, and bytes “10 to 17”. Each of the base-pattern pairs has a length of 8 bytes, which is equal to the bus width of the memory 4. Each of the 8-byte base-pattern pairs is constituted by identical 4-byte base patterns disposed next to each other. For example, in the base-pattern pair held in bytes “8 to F”, a 4-byte base pattern of a data string “00000001(H)” is disposed at a first 4-byte part, i.e., bytes “8 to B”, and at a last 4-byte part, i.e., bytes “C to F”.

In the shift pattern 421 illustrated in FIG. 3, the 7th byte in the base-pattern pair held in bytes “0 to 7” is “00(H)”, i.e., “00000000(2)”, whereas the F-th byte in the base-pattern pair held in bytes “8 to F” is “01(H)”, i.e., “00000001(2)”. Additionally, the 17-th byte in the base-pattern pair held in bytes “10 to 17” is “02(H)”, i.e., “00000010(2)”, whereas the 1F-th byte in the base-pattern pair held in bytes “18 to 1F” is “04(H)”, i.e., “00000100(2)”. Furthermore, the 27-th byte in the base-pattern pair held in bytes “20 to 27” is “08(H)”, i.e., “00001000(2)”, whereas the 2F-th byte in the base-pattern pair held in bytes “28 to 2F” is “10(H)”, i.e., “00010000(2)”.

As described above, in the shift pattern 421 illustrated in FIG. 3, bits holding “1(2)” in binary values of the base patterns are shifted to the left by one bit, for each base-pattern pair. The shift pattern 421 is not limited to the one illustrated in FIG. 3. For example, “1(2)” may be set in values of the base patterns of the first base-pattern pair (bytes “0 to 7”). Additionally, the bits holding “1(2)” in the binary values of the base patterns may be shifted to the right or left by at lest one bit, for each base-pattern pair. Further, each base pattern may include two or more bits that hold “1(2)”.

In the shift pattern 421 illustrated in FIG. 3, the “xx4”-th byte in the base-pattern pair held in bytes “xx0 to xx7” is “80(H)”, i.e., “10000000(2)”, whereas the “xxF”-th byte in the base-pattern pair held in bytes “xx8 to xxF” is “04(H)”, i.e., “00000100(2)”. However, the shift pattern 421 is not limited to this example. For example, the base-pattern pairs from that held in bytes “0 to 7” to that held in bytes “xx0 to xx7” in the shift pattern 421 illustrated in FIG. 3 may be treated as one set, and the shift pattern 421 may be formed by connecting a plurality of the sets. In this case, the “xxF”-th byte in the base-pattern pair held in bytes “xx8 to xxF” may be “00(H)”, i.e., “00000000(2)”.

Alternatively, the base-pattern pairs of the shift pattern 421 may be decided so that the base-pattern pairs are different from one another. In this case, the “xxF”-th byte in the base-pattern pair held in bytes “xx8 to xxF” may be, for example, “11(H)”, i.e., “00010001(2)”. The base-pattern pairs may also be decided so that some base-pattern pairs are the same as another base-pattern pair.

Just like the shift pattern 421 illustrated in FIG. 3, the noise pattern 422 illustrated in FIG. 4 includes a plurality of base-pattern pairs each having a length of 8 bytes, which is equal to the bus width of the memory 4. Each base-pattern pair is constituted by identical 4-byte base patterns disposed next to each other. That is, the base-pattern pairs assigned at 8-byte boundaries by disposing two 4-byte base patterns next to each other are transferred via the memory bus that has the width of 8 bytes.

In the noise pattern 422 illustrated in FIG. 4, the 7-th byte in the base-pattern pair held in bytes “0 to 7” is “55(H)”, i.e., “01010101(2)”, whereas the F-th byte in the base-pattern pair held in bytes “8 to F” is “AA(H)”, i.e., “10101010(2)”. As described above, the noise pattern 422 illustrated in FIG. 4 is a checkered pattern in which “0(2)” and “1(2)” are alternately set in each base pattern. Bits holding “1(2)” in binary values of the base patterns are shifted to the left or right by one bit, for each base-pattern pair.

The noise pattern 422 is not limited to the one illustrated in FIG. 4. For example, the 7-th byte in the base-pattern pair held in bytes “0 to 7” may be “00(H)”, i.e., “00000000(2)”, whereas the F-th byte in the base-pattern pair held in bytes “8 to F” may be “FF(H)”, i.e., “11111111(2)”. That is, “0(2)” and “1(2)” may be alternately set in the base-pattern pairs of the noise pattern 422.

Each of the shift pattern 421 and the noise pattern 422 may partially include the foregoing base-pattern pairs and other given patterns. The test pattern 42 stored in the test-target area 40 is used in the following inspection operations after the test pattern generating unit 21 finishes generating the test pattern 42 and the test pattern transferring unit 22 to be described later finishes transferring the test pattern 42.

When the shift pattern 421 is used as the test pattern 42, the shift pattern 421 stored in the test-target area 40 may be suitably used for inspection of leakage between cells of the memory 4, for example. On the other hand, when the noise pattern 422 is used as the test pattern 42, the noise pattern 422 stored in the test-target area 40 may be suitably used for inspection of noise margins. Additionally, in this embodiment, the test pattern 42 has a size equal to the capacity of the area A or the area B.

The test pattern generating unit 21 may generate the test pattern 42 to be written in the area A by allowing a user to specify a given pattern (input the pattern) via a user interface, not illustrated, of the information processing apparatus 1 or may read out the test pattern 42 previously included in the test program 41. The test pattern generating unit 21 may also generate the test pattern 42 to be written in the area A by combining given base patterns that have been prepared in advance.

The test pattern transferring unit 22 transfers the test pattern 42 that has been written in the area A by the test pattern generating unit 21, between the area A and the area B a predetermined number of times. The test pattern transferring unit 22 includes an address-length generator 211 and a transfer processor 222. The address-length generator 221 generates (calculates and decides) a transfer source address in a transfer source area, a transfer destination address (transfer start address) in a transfer destination area, and a length (transfer length) of the test pattern 42 to be transferred, in order to transfer the test pattern 42 that has been written in the area A by the test pattern generating unit 21 between the area A and the area B.

The address-length generator 221 generates the transfer source address, the transfer destination address, and the transfer length of the test pattern 42 so that the transfer source address and the transfer destination address are shifted by a predetermined amount α when the test pattern 42 is transferred from the area B to the area A. The transfer processor 222 transfers the test pattern 42 between the area A and the area B on the basis of the transfer source address, the transfer destination address, and the transfer length of the test pattern 42 that have been generated by the address-length generator 221. For example, the transfer processor 222 copies data written in an area that starts from the transfer source address in the transfer source area and has a size equal to the transfer length, and overwrites (transfers) the data in an area that starts from the transfer destination address and has a size equal to the transfer length.

As described above, the test pattern transferring unit 22 repeatedly transfers the test pattern 42, which has been written in the area A by the test pattern generating unit 21, between the area A and the area B a predetermined number of times by using the address-length generator 221 and the transfer processor 222. Concrete functions of the test pattern transferring unit 22 will be described later. The determining unit 23 inspects the normality of the areas A and B between which the test pattern 42 is transferred by the test pattern transferring unit 22, i.e., the normality of the data stored in the test-target area 40. That is, the determining unit 23 inspects whether or not data is correctly written in and read out from the test-target area 40.

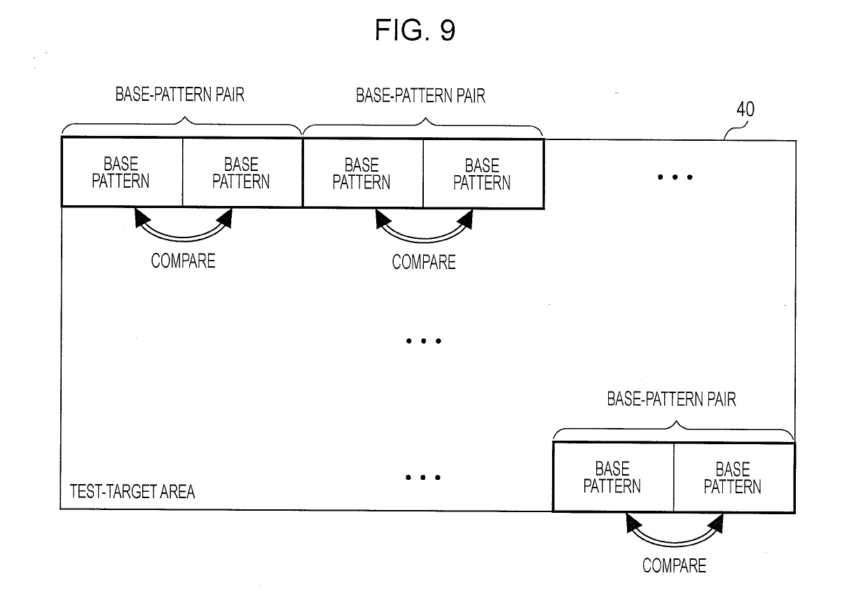

For example, the determining unit 23 compares the base patterns disposed next to each other in the base-pattern pair of the test pattern 42 that has been transferred from one of the areas A and B to the other of the areas A and B, thereby determining whether or not the base patterns disposed next to each other are identical to one another. FIG. 9 is a diagram illustrating comparison of adjacent data patterns in the test-target area 40 of the memory 4 performed by the determining unit 23 according to this embodiment.

As illustrated in FIG. 9, the determining unit 23 compares, for each of the base-pattern pairs of the test pattern 42 that has been transferred within the test-target area 40, the base patterns disposed next to each other in the base-pattern pair and determines whether or not the two base patterns are identical to one another. When the determining unit 23 determines, for all base-pattern pairs of the test pattern 42, that the two base patterns of each of the base-pattern pairs of the test pattern 42 are identical to one another, the determining unit 23 determines that the data is transferred successfully in the memory 4.

When the determining unit 23 determines that data is transferred successfully after transfer has been performed by the test pattern transferring unit 22 the predetermined number of times, the test pattern 42 that has been transferred within the test-target area 40 may be used in various inspection operations, such as the aforementioned ones, as data of the shift pattern 421 or the noise pattern 422. The various inspection operations may be performed by using existing methods and, therefore, the description thereof is omitted.

In contrast, when the determining unit 23 determines that the two base patterns of any of the base-pattern pairs are not identical to one another, the determining unit 23 determines that a failure has occurred in data transfer performed in the memory 4, and outputs an error. For example, the determining unit 23 may display an error message on a monitor, not illustrated, of the information processing apparatus 1 or may store an error log in the I/O device 5, such as an HDD.

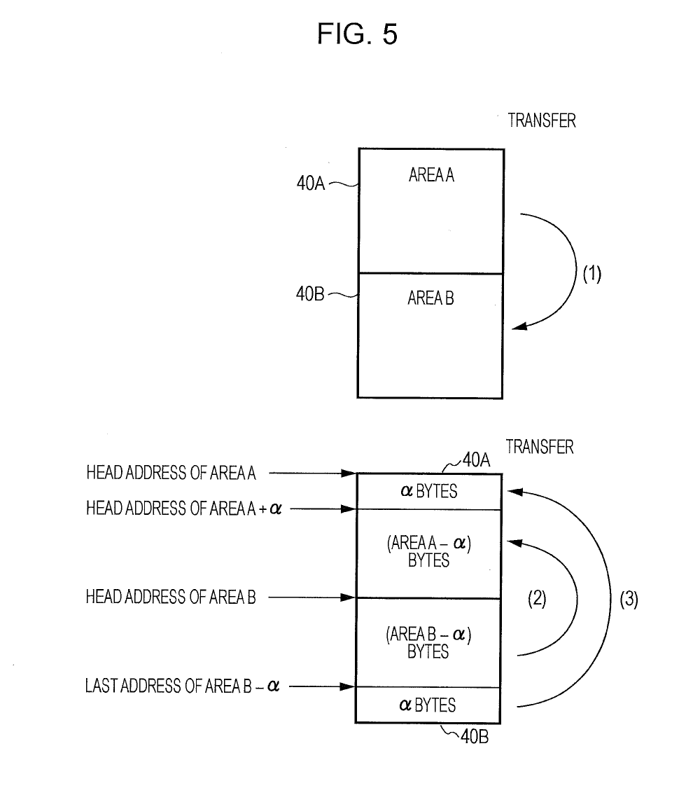

Concrete functions of the test pattern transferring unit 22 according to this embodiment will now be described using FIGS. 5 to 8. FIG. 5 is a diagram for describing a procedure of burst transfer performed by the test pattern transferring unit 22 according to this embodiment. An arrow (1) in FIG. 5 represents a burst transfer process performed from the area A to the area B by the test pattern transferring unit 22, whereas arrows (2) and (3) represent burst transfer processes performed from the area B to the area A.

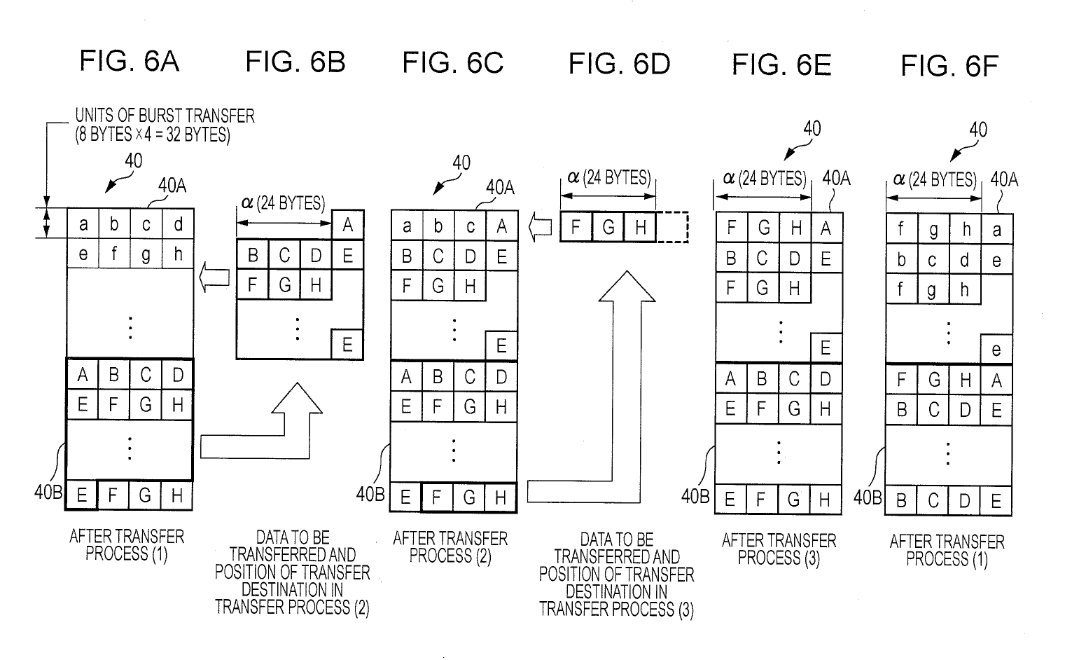

FIGS. 6A to 6F are diagrams illustrating arrangements of data in the test-target area 40 of the memory 4 when the test pattern transferring unit 22 according to this embodiment performs burst transfer.

FIG. 6A is a diagram illustrating the test-target area 40 after the test pattern transferring unit 22 has performed the burst transfer process (1). FIG. 6B is a diagram illustrating data to be transferred and a position of the transfer destination in the burst transfer process (2) to be performed by the test pattern transferring unit 22. FIG. 6C is a diagram illustrating the test-target area 40 after the test pattern transferring unit 22 has performed the burst transfer process (2). FIG. 6D is a diagram illustrating data to be transferred and a position of the transfer destination in the burst transfer process (3) to be performed by the test pattern transferring unit 22. FIG. 6E is a diagram illustrating the test-target area 40 after the test pattern transferring unit 22 has performed the burst transfer process (3). FIG. 6F is a diagram illustrating the test-target area 40 after the test pattern transferring unit 22 has performed the burst transfer process (1) in the test-target area 40 illustrated in FIG. 6E.

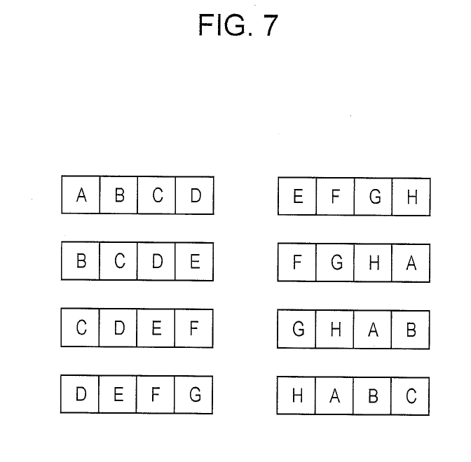

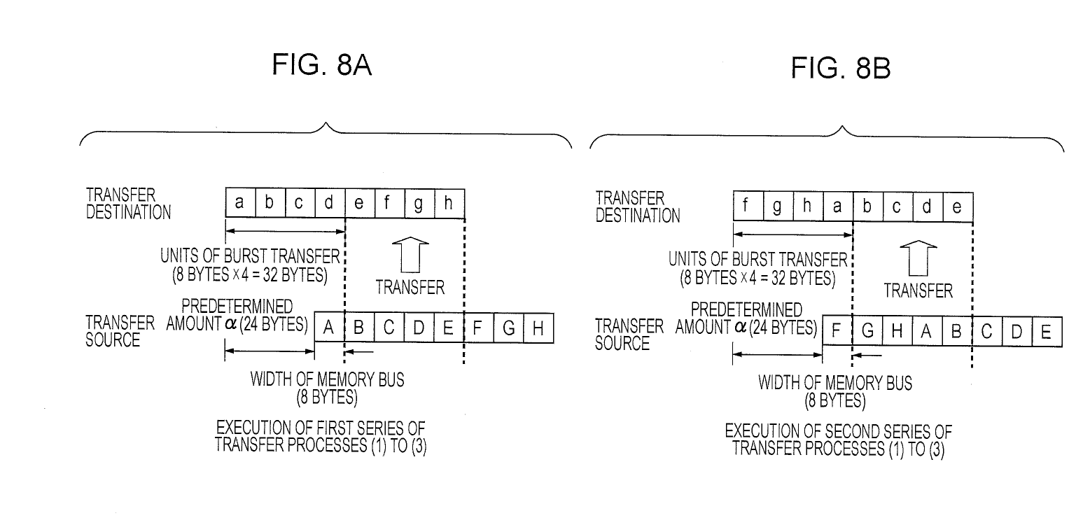

FIG. 7 is a diagram illustrating a data pattern generated when the test pattern transferring unit 22 according to this embodiment performs burst transfer processes. FIGS. 8A and 8B are diagrams illustrating burst-transfer unit data to be transferred in the burst transfer processes performed by the test pattern transferring unit 22 according to this embodiment.

FIG. 8A is a diagram illustrating burst-transfer unit data transferred by the test pattern transferring unit 22 in the first series of burst transfer processes illustrated in FIGS. 6A to 6E. FIG. 8B is a diagram illustrating burst-transfer unit data transferred by the test pattern transferring unit 22 in a second series of burst transfer processes, i.e., the burst transfer process (1) illustrated in FIG. 6F and the following burst transfer processes (2) to (3), in the test-target area 40 illustrated in FIG. 6E.

The test pattern transferring unit 22 repeats the series of transfer processes (1) to (3) illustrated in FIG. 5 a predetermined number of times by using the address-length generator 221 and the transfer processor 222. The description will be given below for a case where the transfer process (1) for transferring the test pattern 42 from the area A to the area B and the transfer processes (2) and (3) from the area B to the area A performed by the test pattern transferring unit 22 are set as steps 1 and 2, respectively.

1-1 Step 1 (Transfer Process (1) from Area A to Area B)

In the transfer process (1) illustrated in FIG. 5, the address-length generator 221 and the transfer processor 222 transfer, to the area B, the test pattern 42 that has been written in the area A by the test pattern generating unit 21. In the transfer process (1), the address-length generator 221 decides the head address of the area A as the transfer source address, decides the head address of the area B as the transfer destination address, and decides the size of the area A (=the size of the area B) as the transfer length of the test pattern 42.

The transfer processor 222 transfers (copies) the data (test pattern 42) having a size equal to the size of the area A from the head address of the area A, to an area having a size equal to the size of the area B from the transfer destination address of the area B, on the basis of the transfer source address, the transfer destination address, and the transfer length that have been generated by the address-length generator 221.

1-2 Step 2 (Transfer Processes (2) and (3) from Area B to Area A)

In the transfer processes (2) and (3) illustrated in FIG. 5, the address-length generator 221 and the transfer processor 222 transfer, to the area A, the test pattern 42 that has been transferred to the area B. As described above, before the test pattern 42 is transferred to the area A from the area B, the address-length generator 221 generates the transfer source address, the transfer destination address, and the transfer length of the test pattern 42 on the basis of the predetermined amount α. The predetermined amount α is equal to, for example, a difference between the bus width of the memory 4 and the unit size in which the test pattern 42 is transferred within the test-target area 40 of the memory 4 by the CPU 2 (i.e., the burst transfer size in this embodiment).

Accordingly, the predetermined amount α in this embodiment is equal to 24 bytes, i.e., the difference between the burst transfer size, i.e., 32 bytes, and the bus width of the memory, i.e., 8 bytes.

1-2-1 Step 2-1 (Transfer Process from Area B to Area A)

In the transfer process (2), the address-length generator 221 decides the head address of the area B as the transfer source address. The address-length generator 221 also decides an address that is shifted (e.g., shifted behind) by the predetermined amount α from the write start address (i.e., the head address of the area A) from which the data pattern generating unit 21 has written the test pattern 42 in the area A, as the transfer destination address (first transfer destination address or first transfer start address).

The address-length generator 221 further generates (decides) as the transfer length of the test pattern 42, a size obtained by subtracting the predetermined amount α from the size of the area B. For example, the address-length generator 221 decides, as the transfer length, the size of an area between the head address of the area B and an address obtained by subtracting the predetermined amount α from the last address of the area B. In the example illustrated in FIGS. 6A to 6F, the address-length generator 221 decides the head address of the area B as the transfer source address. The address-length generator 221 also decides, as the first transfer destination address, the address that is shifted from the head address of the area A by the predetermined amount α, i.e., 24 bytes, as illustrated in FIG. 6B.

Further, as illustrated in FIG. 6A, the address-length generator 221 decides, as the transfer length, the size of the area between the head address of the area B and the address obtained by subtracting the predetermined amount α, i.e., 24 bytes, from the last address of the area B. Meanwhile, in FIGS. 6A to 6F, a block denoted by each of “a” to “h” and “A” to “H” represents an 8-byte base-pattern pair. Since the size of the cache memory 3 is set as the unit size of burst transfer in this embodiment as described above, the test pattern transferring unit 22 transfers as many blocks as a value obtained by dividing the size of the cache memory 3, i.e., 32 bytes, by the bus width of the memory (=the size of the base-pattern pair), i.e., 8 bytes, namely, four blocks, during one burst transfer operation.

For convenience, the test pattern 42 written in the area A by the test pattern generating unit 21 is represented with “a” to “h” in the example illustrated in FIGS. 6A to 6F, whereas the test pattern 42 transferred to the area B in the transfer process (1) illustrated in FIG. 5 is represented with “A” to “H”. However, the data represented with “a” to “h” and the data represented with “A” to “H” are the same data. Accordingly, in the state illustrated in FIG. 6A, the test patterns 42 in the areas A and B are the same.

In the example illustrated in FIGS. 6A to 6F, the test pattern 42 is represented as data in which the base-pattern pairs “A” to “H” (“a” to “h”) are cyclically repeated for convenience, but the test pattern 42 is not limited to this example. For example, as described above, the base patterns may be decided so that base-pattern pairs of the test pattern 42 are different from one another, or so that some base-pattern pairs are the same as another base-pattern pair.

In the transfer process (2) illustrated in FIG. 5, the transfer processor 222 transfers (copies) consecutive data (part of the test pattern 42) that starts from the head address of the area B and has a size equal to a value obtained by subtracting the predetermined amount α from the size of the area B, to an area that starts from an address that is shifted from the head address of the area A by the predetermined amount α and has the same size. That is, the transfer processor 222 transfers the test pattern 42 stored in the area between the head address of the area B and the address determined by subtracting the predetermined amount α from the last address of the area B, using as the first transfer destination address the address that is shifted from the head address of the area A by the predetermined amount α.

In the example illustrated in FIGS. 6A to 6F, the transfer processor 222 transfers the test pattern 42 stored in the area between the head address of the area B and the address obtained by subtracting the predetermined amount α, i.e., 24 bytes, from the last address of the area B as illustrated in FIGS. 6B and 6C. The first transfer destination address of the area A serving as the transfer destination at this time is an address shifted from the head address of the area A by the predetermined amount α, i.e., 24 bytes.

1-2-2 Step 2-2 (Transfer Process (3) from Area B to Area A)

In the transfer process (3) illustrated in FIG. 5, the address-length generator 221 decides the address obtained by subtracting the predetermined amount α from the last address of the area B as the transfer source address, and decides the head address of the area A as the transfer destination address (second transfer destination address or second transfer start address).

The address-length generator 221 also decides the predetermined amount α as the transfer length of the test pattern 42. In the example illustrated in FIGS. 6A to 6F, the address-length generator 221 decides as the transfer source address the address obtained by subtracting the predetermined amount α, i.e., 24 bytes, from the last address of the area B as illustrated in FIG. 6C. The address-length generator 221 further decides the head address of the area A as the second transfer destination address.

Moreover, as illustrated in FIG. 6D, the address-length generator 221 decides the predetermined amount α, i.e., 24 bytes, as the transfer length. In the transfer process (3) illustrated in FIG. 5, the transfer processor 222 then transfers the data (part of the test pattern 42) that has a size equal to the predetermined amount α from the address obtained by subtracting the predetermined amount α from the last address of the area B, to the head address of the area A which serves as the second transfer destination address.

In the example illustrated in FIGS. 6A to 6F, the transfer processor 222 transfers the data (part of the test pattern 42) that has the size equal to the predetermined amount α and starts from the address obtained by subtracting the predetermined amount α from the last address of the area B as illustrated in FIGS. 6D and 6E. The second transfer destination address of the area A serving as the transfer destination at this time is the head address of the area A. After the test pattern transferring unit 22 has performed the transfer process (3), the test pattern transferring unit 22 determines whether or not the transfer processes (1) to (3) have been performed a predetermined number of times. When it is determined that the transfer processes (1) to (3) have not been performed the predetermined number of times, the test pattern transferring unit 22 further repeats the transfer processes (1) to (3).

In the example illustrated in FIGS. 6A to 6F, the test pattern transferring unit 22 determines whether or not the transfer processes (1) to (3) have been performed the predetermined number of times after performing of the transfer process (3) (see FIG. 6E). When the test pattern transferring unit 22 determines that the transfer processes (1) to (3) have not been performed the predetermined number of times, the test pattern transferring unit 22 performs the next transfer processes (1) to (3). The test pattern transferring unit 22 transfers the data stored in the area A illustrated in FIG. 6E to the area B in the next transfer process (1) (see FIG. 6F), and performs the transfer processes (2) and (3) in the test-target area 40 illustrated in FIG. 6F based on the aforementioned procedure.

As described above, the CPU 2 performs the series of transfer processes (1) to (3) illustrated in FIG. 5 in the predetermined number of times by using the test pattern transferring unit 22, thereby performing the memory test on the test-target area 40 of the memory 4. After the test pattern transferring unit 22 performs the series of the burst transfer processes (1) to (3) once, data patterns that appear as consecutive data in the test-target area 40 after the burst transfer processes is shifted by the predetermined amount α from data patterns that appear as consecutive data in the test-target area 40 before transfer (see FIGS. 6A and 6F).

In the example illustrated in FIGS. 6A to 6F, data patterns that appear as consecutive data in the test-target area 40 before the transfer, i.e., data having a length within the unit size of burst transfer, are “abcd” and “efgh” (“ABCD” and “EFGH”). On the other hand, the data patterns that appear as consecutive data in the test-target area 40 after the transfer, i.e., data having a length within the unit size of burst transfer, are “FGHA” and “BCDE”.

Accordingly, the test pattern transferring unit 22 performs the series of burst transfer processes (1) to (3) the predetermined number of times, whereby eight data patterns appear as consecutive data in the test-target area 40 as illustrated in FIG. 7. The kinds (number) of the data patterns that appear as the consecutive data in this test-target area 40 differ depending on the unit size of burst transfer (the size of the cache memory 3), the size of one base-pattern pair (the bus width of the memory 4), variations of base patterns, and arrangement conditions of base-pattern pairs, and so forth.

As described above, when the transfer source address and the transfer destination address are shifted by the predetermined amount α illustrated in FIGS. 6A to 6F in the transfer processes (2) and (3) illustrated in FIG. 5, the data stored in the cache memory 3 one after another is shifted and, therefore, positions of boundaries of burst transfer where data transfer is interrupted may be made variable. For example, as illustrated in FIG. 8A, boundaries of burst transfer exist between “A” and “B” and between “E” and “F” in the first series of burst transfer processes (1) to (3). As illustrated in FIG. 8B, boundaries of burst transfer exist between “B” and “C” and between “F” and “G” in the second series of burst transfer processes (1) to (3).

As described above, the test pattern transferring unit 22 according to this embodiment shifts the transfer source address and the transfer destination address by the predetermined amount α, thereby making positions of boundaries of burst transfer variable in accordance with the number of times when the series of transfer processes (1) to (3) is performed. That is, the transfer destination address is shifted by a value obtained by subtracting the bus width of the memory from the unit size of burst transfer at the time of data transfer, whereby the test pattern 42 of every type may be generated which includes the preceding and following base-pattern pairs that are made consecutive in the cache memory 3.

Since pieces of test data that are next to each other in the test pattern 42 may be transferred in a burst as data that is consecutive in various combinations in the cache memory 3 during the memory test, the accuracy of the test may be improved. Meanwhile, determination may be performed by the determining unit 23 every time the test pattern transferring unit 22 performs the aforementioned series of transfer processes (1) to. (3).

When the determining unit 23 determines that adjacent base patterns are not identical in this determination, the process may be terminated upon detection of this error. Therefore, a time spent on the test may be shortened and an address in the test-target area 40 where the error has occurred may be identified. In addition, the determination may be performed by the determining unit 23 after the test pattern transferring unit 22 performs the aforementioned series of processes (1) to (3) a predetermined number of times.

Compared with the case where the determination is performed by the determining unit 23 every time the test pattern transferring unit 22 performs the series of transfer processes (1) to (3), a time spent on the test may be further shortened. In this embodiment, the description will be given below for a case where the determination is performed by the determining unit 23 after the test pattern transferring unit 22 performs the aforementioned series of transfer processes (1) to (3) in the predetermined number of times.

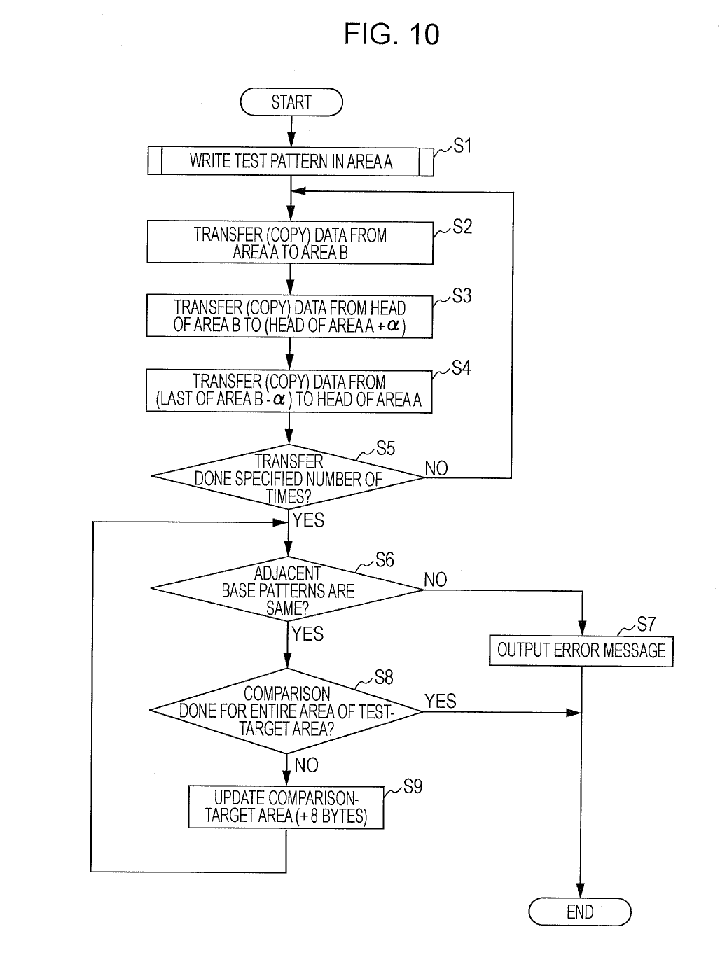

The description will now be given for a testing method for testing the test-target area 40 of the memory 4 performed by the test pattern generating unit 21, the test pattern transferring unit 22, and the determining unit 23 according to this embodiment that are configured in the aforementioned manner. FIG. 10 is a flowchart for describing the testing method for testing the memory 4 according to this embodiment.

First, the test pattern generating unit 21 of the CPU 2 generates the test pattern 42 or reads out the test pattern 42 from the memory 4 or the like, and writes the test pattern 42 in the area A of the test-target area 40 of the memory 4 (S1). Here, the size of the written test pattern 42 is equal to the capacity of the area A. Additionally, the head address of the area A is set as the write start address. Next, the test pattern transferring unit 22 transfers (copies) the test pattern 42 that has been written in the area A, to the area B in a burst (S2, the transfer process (1)). This transfer is performed by transferring the test pattern 42 having a size that is equal to the capacity of the area A (=the capacity of the area B) using the head address of the area A and the head address of the area B as the transfer source address and the transfer destination address, respectively.

The test pattern transferring unit 22 then transfers (copies), to the area A in a burst, the test pattern 42 stored in an area between the head address of the area B and an address obtained by subtracting the predetermined amount α from the last address of the area B (S3, the transfer process (2)). This transfer is performed by transferring the test pattern 42 having a size that is equal to a result of subtraction of the predetermined amount α from the capacity of the area B, using as the first transfer destination address the address that is shifted from the head address of the area A by the predetermined amount α.

The test pattern transferring unit 22 also transfers (copies), to the area A in a burst, the test pattern 42 stored in an area between the last address of the area B and the address obtained by subtracting the predetermined amount α from the last address of the area B (S4, the transfer process (3)). This transfer is performed by transferring the test pattern 42 having a size equal to the predetermined amount α, using the head address of the area A as the second transfer destination address.

The test pattern transferring unit 22 then determines whether or not the series of processing S2 to S4 (transfer processes (1) to (3)) has been performed a predetermined number of times (S5). When the series of processing S2 to S4 has not been performed the predetermined number of times (NO in S5), the process returns to S2. On the other hand, when the series of processing S2 to S4 has been performed with the predetermined number of times (YES in S5), the determining unit 23 compares adjacent base patterns of each base-pattern pair of the test pattern 42 that has been transferred within the test-target area 40, and determines whether or not the compared base patterns are identical to one another (S6).

At this time, the determining unit 23 determines whether or not a first half base pattern matches a last half base pattern stored in a comparison-target area on the basis of the comparison-target area which indicates the base-pattern pair subjected to comparison. An area between the head address of the test-target area 40 and an address that is shifted from the head address of the test-target area 40 by an amount equal to the size of the base-pattern pair is set as an initial value of the comparison-target area. When the determining unit 23 determines that the base patterns of the base-pattern pair corresponding to the comparison-target area are not identical (NO in S6), the determining unit 23 determines that a failure has occurred in data transfer performed in the memory 4, and outputs an error message (S7).

On the other hand, when the determining unit 23 determines that the base patterns of the base-pattern pair corresponding to the comparison-target area are identical (YES in S6), the determining unit 23 determines whether or not the comparison in S6 has been done for the entire area of the test-target area 40 (S8). For example, the determining unit 23 performs this determination by determining whether or not the address of the comparison-target area indicates the last address of the test-target area 40.

When the determining unit 23 determines that the comparison in S6 has not been done for the entire area of the test-target area 40 (NO in S8), the determining unit 23 updates the comparison-target area (S9). The process then returns to S6. In S6, the base patterns of the base-pattern pair corresponding to the updated comparison-target area are compared with each other on the basis of the updated comparison-target area.

The update of the comparison-target area is performed in S9 by adding the size of the base-pattern pair, i.e., 8 bytes, to the address of the comparison-target area. On the other hand, when the determining unit 23 determines that the comparison in S6 has been done for the entire area of the test-target area 40 (YES in S8), the determining unit 23 determines that data transfer has been done successfully in the test-target area 40 in the memory test. The process then terminates. After the termination of the process, the test pattern 42 that has been transferred within the test-target area 40 may be used in various inspection operations thereafter as the shift pattern 421 or the noise pattern 422 as described above.

As described above, the test pattern generating unit 21 according to this embodiment generates the test pattern 42 that includes a plurality of base-pattern pairs each constituted by identical base patterns disposed next to each other. The determining unit 23 according to this embodiment compares, for each of the base-pattern pairs of the test pattern 42 that has been transferred within the test-target area 40 by the test pattern transferring unit 22, the base patterns disposed next to each other.

By setting the same value in the adjacent base patterns of each base-pattern pair, the normality of transferred data may be guaranteed even when the test pattern 42 is repeatedly transferred within the test-target area 40. Accordingly, whether or not data transfer is successfully performed in the test-target area 40 may be determined by simply determining whether or not the adjacent base patterns are identical. With this configuration, a process of comparing data resulting from repetition of burst transfer with data of expected values simulated in advance and a process of comparing data stored in a transfer source with data stored in a transfer destination every time burst transfer is performed may be omitted and, therefore, a time spent on the test may be shortened.

The test pattern transferring unit 22 according to this embodiment transfers the test pattern 42, which has been transferred to the area B, to the area A. At this time, an address that is shifted by the predetermined amount α from the write start address from which the test pattern 42 has been written in the area A is set as the transfer destination address. By shifting the addresses of the transfer source and the transfer destination by the predetermined amount α in this manner, positions of boundaries of burst transfer may be made variable in accordance with the number of times the series of transfer processes (1) to (3) is performed. That is, by shifting the transfer destination address by an amount equal to a value obtained by subtracting the bus width of the memory from the unit size of burst transfer, the test pattern 42 of every kind may be generated in which the preceding base-pattern pair and the following base-pattern pair are consecutive in the cache memory 3.

Since various combinations of pieces of test data disposed next to each other in the test pattern 42 may be transferred as pieces of data that are consecutive in the cache memory 3 in the memory test, the accuracy of the memory test may be improved. Further, identical base patterns are disposed next to each other in each base-pattern pair according to this embodiment. In addition, the test pattern 42 that has been prepared by the test pattern generating unit 21 at first may be transferred in a burst while changing positions of boundaries of burst transfer.

Accordingly, without generating a plurality of test patterns to change the positions of the boundaries of burst transfer, various combinations of data that are consecutive in the cache memory 3 may be transferred in a burst by transferring the test pattern 42 the predetermined number of times. Accordingly, a time taken by the test pattern generating unit 21 to generate the test pattern and a time taken by the determining unit 23 to compare the pieces of data may be shortened.

While the desirable embodiment has been described in detail above, the technique disclosed herein is not limited to the specific embodiment and may be variously modified and altered within the scope not departing from the spirit thereof. For example, the description has been given in this embodiment for the case where the test pattern transferring unit 22 performs the transfer process (2) (S3 in FIG. 10) before performing the transfer process (3) (S4 in FIG. 10). However, the order of the transfer processes is not limited to this example. For example, the test pattern transferring unit 22 may perform the transfer process (3) (S4 in FIG. 10) before performing the transfer process (2) (S3 in FIG. 10).

In addition, the description has been given in this embodiment for the case where the predetermined amount α is equal to a difference between the unit size of burst transfer and the bus width of the memory. However, the predetermined amount α is not limited to this value, and may be set equal to the bus width of the memory. Furthermore, the description has been given in this embodiment for the case where four divided data portions are transferred in one burst transfer process. However, the number of divided data portions is not limited to this value, and may be set to a given value in accordance with the size of the cache memory 3 and the bus width of the memory 4.

The description has been given in this embodiment for the case where the size of the base-pattern pair is 8 bytes and the size of the base pattern is 4 bytes. However, the sizes of the base-pattern pair and the base pattern are not limited to these values, and may be decided in accordance with the bus width of the memory 4. For example, when the bus width of the memory 4 is 16 bytes, the size of the base pattern may be set equal to a half of the bus width of the memory, i.e., 8 bytes, and the size of the base-pattern pair may be set equal to 16 bytes by disposing two base patterns next to each other.

Furthermore, the description has been given in this embodiment for the case where the test pattern 42 is transferred in a burst within the test-target area 40 of the memory 4 by the CPU 2 serving as a processing section. However, the configuration is not limited to this example. For example, the information processing apparatus 1 may include a direct memory access (DMA) controller that serves as the processing section, and the DMA controller may perform operations of the test pattern generating unit 21 and the test pattern transferring unit 22.

This configuration may reduce the load of the CPU 2, compared with the case where the CPU 2 has the functions of the test pattern generating unit 21 and the test pattern transferring unit 22. Additionally, a program (test program) for realizing the functions of the test pattern generating unit 21 (generating unit), the test pattern transferring unit 22 (transferring unit), the address-length generator 221, the transfer processor 222, and the determining unit 23 may be provided after the program is recorded on a computer-readable recording medium, e.g., a magnetic disk such as a flexible disk, an optical disc such as a compact disc (CD) (CD-ROM, CD-R, CD-RW, or the like), a digital versatile disc (DVD) (DVD-ROM, DVD-RAM, DVD-R, DVD+R, DVD-RW, DVD+RW, HD DVD, or the like), or a blu-ray disc; or a magneto-optical disk. A computer then reads the program from the recording medium, transfers and stores the program in an internal or external storage device, and uses the stored program. Alternatively, the program may be recorded in a storage device (recording medium), such as a magnetic disk, an optical disc, or a magneto-optical disk, and the program may be provided to the computer from the storage device via a communication network.

When the functions of the test pattern generating unit 21, the test pattern transferring unit 22, the address-length generator 221, the transfer processor 222, and the determining unit 23 are implemented, the program stored in the internal storage device (such as the memory 4 (storage section) and the I/O device 5 of the information processing apparatus 1 in this embodiment) is executed by a microprocessor of the computer (the CPU 2 (processing section) of the information processing apparatus 1 in this embodiment). At this time, the computer may read and execute the program recorded on a recording medium.

In this embodiment, the computer is a concept including hardware and an operating system, and indicates hardware that operates under control of the operating system. When the hardware is caused to operate by an application program alone without using the operating system, the hardware corresponds to the computer. The hardware includes at least a microprocessor, such as a CPU, and a device for reading a computer program recorded on a recording medium. In this embodiment, the information processing apparatus 1 has the functions of the computer.

With the disclosed technique, a time spent on tests performed on storage sections of information processing apparatuses may be shortened. In addition, with the disclosed technique, the accuracy of the tests performed on the storage sections of the information processing apparatuses may be improved.

As mentioned above, the present invention has been specifically described for better understanding of the embodiments thereof and the above description does not limit other aspects of the invention. Therefore, the present invention can be altered and modified in a variety of ways without departing from the gist and scope thereof.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present inventions have been described in detail, it should be understood that the various changes, substitutions, and alterations could be made hereto without departing from the spirit and scope of the invention.

What is claimed is:

1. A testing method for testing whether or not data is correctly written in and read from a test-target area of a storage unit included in an information processing apparatus, by using a processor included in the information processing apparatus, the testing method comprising:
writing, in a first area of the test-target area, a test pattern including a base-pattern pair constituted by identical base patterns disposed next to each other;
transferring, to a second area of the test-target area, the test pattern that has been written in the first area;
transferring, to the first area, the test pattern that has been transferred to the second area, using as a transfer start address an address that is shifted by a predetermined amount from a write start address from which the test pattern has been written in the first area; and
inspecting whether or not the data is correctly written in and read from the test-target area by comparing the base patterns disposed next to each other in the base-pattern pair included in the test pattern that has been transferred from one of the first area and the second area to the other of the first area and the second area and by determining whether or not the base patterns disposed next to each other are identical to one another.

2. The testing method according to claim 1,
wherein the transferring of the test pattern from the first area to the second area and the transferring of the test pattern from the second area to the first area are performed a predetermined number of times, and whether or not the data is correctly written in and read from the test-target area is inspected by comparing the base patterns disposed next to each other in the base-pattern pair included in the test pattern that has been transferred from one of the first area and the second area to the other of the first area and the second area and by determining whether or not the base patterns disposed next to each other are identical to one another.

3. The testing method according to claim 2,
wherein the test pattern includes a plurality of the base-pattern pairs each constituted by identical base patterns disposed next to each other, and the comparing of the base patterns is performed by comparing, for each of the plurality of base-pattern pairs included in the test pattern that has been transferred from one of the first area and the second area to the other of the first area and the second area, the base patterns disposed next to each other in the base-pattern pair.

4. The testing method according to claim 3, wherein the predetermined amount is equal to a bus width of the storage unit, or a difference between the bus width of the storage unit and a transfer unit size in which the test pattern is transferred within the test-target area by using the processor.

5. The testing method according to claim 4,
wherein the transferring of the test pattern within the test-target area is performed in a burst transfer mode by using the processor, and each base-pattern pair has a size that is equal to the bus width of the storage unit.

6. The testing method according to claim 5,
wherein the first area and the second area have the same capacity, the test pattern has a size that is equal to the capacity of the first area or the second area, the writing of the test pattern in the first area is performed by writing the test pattern using the head address of the first area as the write start address, the transferring, to the second area, of the test pattern that has been written in the first area is performed by transferring the test pattern using the head address of the second area as a transfer start address, and the transferring, to the first area, of the test pattern that has been transferred to the second area, is performed by transferring, using as a first transfer start address an address that is shifted by the predetermined amount from the head address of the first area, the test pattern stored in an area between the head address of the second area and an address that results from subtraction of the predetermined amount from the last address of the second area, and by transferring, using as a second transfer start address the head address of the first area, the test pattern stored in an area between the last address of the second area and the address that results from subtraction of the predetermined amount from the last address of the second address.

7. The testing method according to claim 6, wherein the comparing of the base patterns is performed after the transferring of the test pattern from the first area to the second area and the transferring of the test pattern from the second area to the first area are performed in a predetermined number of times.

8. The testing method according to claim 6, wherein the comparing of the base patterns is performed every time the transferring of the test pattern from the first area to the second area and the transferring of the test pattern from the second area to the first area are performed.

9. A non-transitory, computer readable storage medium storing a test program causing an information processing apparatus including a processor and a storage unit to execute a process, the process comprising:
writing, in a first area of a test-target area of the storage unit, a test pattern including a base-pattern pair constituted by identical base patterns disposed next to each other;
transferring, to a second area of the test-target area, the test pattern that has been written in the first area;
transferring, to the first area, the test pattern that has been transferred to the second area, using as a transfer start address an address that is shifted by a predetermined amount from a write start address from which the test pattern has been written in the first area; and
inspecting whether or not data is correctly written in and read from the test-target area by comparing the base patterns disposed next to each other in the base-pattern pair included in the test pattern that has been transferred from one of the first area and the second area to the other of the first area and the second area and by determining whether or not the base patterns disposed next to each other are identical to one another.

10. The non-transitory, computer readable storage medium according to claim 9,
wherein the transferring of the test pattern from the first area to the second area and the transferring of the test pattern from the second area to the first area are performed a predetermined number of times, and whether or not the data is correctly written in or read from the test-target area is inspected by comparing the base patterns disposed next to each other in the base-pattern pair included in the test pattern that has been transferred from one of the first area and the second area to the other of the first area and the second area and by determining whether or not the base patterns disposed next to each other are identical to one another.

11. The non-transitory, computer readable storage medium according to claim 10,
wherein the test pattern includes a plurality of the base-pattern pairs each constituted by identical base patterns disposed next to each other, and the comparing of the base patterns is performed by comparing, for each of the plurality of base-pattern pairs included in the test pattern that has been transferred from one of the first area and the second area to the other of the first area and the second area, the base patterns disposed next to each other in the base-pattern pair.

12. The non-transitory, computer readable storage medium according to claim 11, wherein the predetermined amount is equal to a bus width of the storage unit, or a difference between the bus width of the storage unit and a transfer unit size in which the test pattern is transferred within the test-target area by using the processor.

13. The non-transitory, computer readable storage medium according to claim 12,
wherein the transferring of the test pattern within the test-target area is performed in a burst transfer mode by using the processor, and each base-pattern pair has a size that is equal to the bus width of the storage unit.

14. The non-transitory, computer readable storage medium according to claim 13, wherein the comparing of the base patterns is performed after the transferring of the test pattern from the first area to the second area and the transferring of the test pattern from the second area to the first area are performed a predetermined number of times.

15. A testing apparatus for performing a test, comprising:
a storage having a test-target area on which the testing apparatus performs the test; and
a processor configured to execute a procedure, the procedure including
writing, in a first area of the test-target area, a test pattern including a base-pattern pair constituted by identical base patterns disposed next to each other,
transferring, to a second area of the test-target area, the test pattern that has been written in the first area, and configured to transfer, to the first area, the test pattern that has been transferred to the second area, using as a transfer start address an address that is shifted by a predetermined amount from a write start address from which the test pattern has been written in the first area, and
inspecting whether or not data is correctly written in and read from the test-target area by comparing the base patterns disposed next to each other in the base-pattern pair included in the test pattern that has been transferred from one of the first area and the second area to the other of the first area and the second area and by determining whether or not the base patterns disposed next to each other are identical to one another.
